(19) United States
(12) Patent Application Publication
(10) Pub. No.: US 2014/0370715 A1
(43) Pub. Date: Dec. 18, 2014

(54) PLASMA PROCESSING METHOD AND SUBSTRATE PROCESSING APPARATUS

(71) Applicant: WINTEL CO., LTD., Hwaseong-si (KR)

(72) Inventors: Seng-Hyun CHUNG, Hwaseong-si (KR); Hyang-Joo LEE, Seoul (KR)

(21) Appl. No.: 14/472,781

(22) Filed: Aug. 29, 2014

Related U.S. Application Data
(63) Continuation of application No. PCT/KR2013/001360, filed on Feb. 21, 2013.

(30) Foreign Application Priority Data
Mar. 9, 2012 (KR) 10-2012-0024551

(51) Int. Cl. B81C 1/00; H01L 21/67

(52) U.S. Cl. CPC B81C 1/00531; H01L 21/67069
USPC 438/714; 156/345.48

(57) ABSTRACT

Provided are a plasma processing method and a substrate processing apparatus. The plasma processing method includes mounting at least one first plasma source and at least one second plasma source on a chamber, supplying a first gas to the first plasma source, supplying a second gas different from the first gas to the second plasma source, applying power to the first plasma source to generate first plasma, applying power to the second plasma source to generate second plasma, and processing a substrate disposed inside the chamber using the first and second plasma.

### CROSS-REFERENCE TO RELATED APPLICATION

This application is a continuation of and claims priority to PCT/KR2013/001360 filed on Feb. 21, 2013, which claims priority to Korea Patent Application No. 10-2012-0024551 filed on Mar. 9, 2012, the entirety of which is hereby incorporated by reference.

### BACKGROUND

1. Technical Field

The present invention described herein generally relates to plasma processing apparatuses and, more particularly, to a plasma processing apparatus using inductively coupled plasma.

2. Description of the Related Art

Deep anisotropic structure etching is one of main techniques for use in manufacturing of semiconductor and fine-structure devices. Deep anisotropic structure etching is a technique applicable to a microelectromechanical system (MEMS). In order to satisfactorily manufacture such devices, it is necessary to strictly control an etching profile.

One of the techniques for forming trenches or holes having vertical sidewalls uses protective coating in a region opened to a trench. A material used to form coating is resistive to an etchant used to etch a trench or a hole. The coating may be successively applied or may be applied at specific points of time during a trench or hole formation process. For example, a silicon substrate is covered with a patterned mask which allows selected regions of the silicon substrate to be exposed to etching. Anisotropic etching includes plasma etching and polymer generating steps that are alternately performed.

For example, anisotropic etching may be performed using a Bosch process. For example, the Bosch process includes a step of plasma-discharging an etch gas such as SF₆ to perform isotropic etching for predetermined time and a step of plasma-discharging a deposition gas such as C₄F₈ to form a protection layer on an etched sidewall. These steps are repeatedly performed. However, there is a need for change from an etch gas to a deposition gas and the gas change requires time. In addition, a wavy scallop is formed on the sidewalls during the Bosch process. Apart from the gas change method, another method is required. A conventional Bosch process is performed using inductively coupled plasma. However, it is necessary to increase an etch rate because a hole is deep.

### SUMMARY

Embodiments of the present invention provide a plasma generating apparatus having a high etch rate and providing an anisotropic etch.

Embodiments of the present invention also provide a plasma processing method having a high etch rate and providing an anisotropic etch.

A plasma processing method according to an embodiment of the present invention may mounting one or more first plasma sources and one or more second plasma sources on a chamber; supplying a first gas to the first plasma sources; supplying a second gas different from the first gas to the second plasma sources; applying power to the first plasma sources to generate first plasma; applying power to the second plasma sources to generate second plasma; and processing a substrate disposed inside the chamber using the first plasma and the second plasma.

In an exemplary embodiment of the present invention, a hole may be formed at the substrate 156 during the step of processing the substrate 156 disposed inside the chamber using the first plasma and the second plasma.

In an exemplary embodiment of the present invention, the first plasma and the second plasma may be alternately generated.

In an exemplary embodiment of the present invention, the first gas may include at least one of a fluorine-containing gas and a chlorine-containing gas. The second gas may include at least one of an oxygen gas, a hydrogen gas, and a carbon-containing gas.

In an exemplary embodiment of the present invention, the first gas may include at least one of SF₆, CF₄, and CHF₃. The second gas may include at least one of C₄F₈, C₃F₆, C₂F₂, oxygen, and hydrogen.

In an exemplary embodiment of the present invention, each of the first and second plasma sources may be an inductive coupled plasma source using a magnetic field.

In an exemplary embodiment of the present invention, each of the first and second plasma sources may be an inductive coupled plasma source using a magnetic field.

In an exemplary embodiment of the present invention, each of the first plasma sources may include a first group through-hole formed at the chamber; a first group dielectric substance mounted in the first group through-hole; first gas supply means for supplying the first gas around the first group dielectric substance; and a first group antenna for generation of first plasma disposed around the first group dielectric substance. Each of the second plasma sources may include a second group through-hole formed at the chamber; a second group dielectric substance mounted in the second group through-hole; second gas supply means for supplying the second gas around the second group dielectric substance; and a second group antenna for generation of second plasma disposed around the second group dielectric substance.

In an exemplary embodiment of the present invention, the first group antenna may be electrically connected to a first RF power source, and the second group antennal may be electrically connected to a second RF power source.

In an exemplary embodiment of the present invention, the first plasma sources may be disposed at regular intervals along a circle having a constant radius in the center of the cylindrical chamber. The second plasma sources may be disposed between the first plasma sources at regular intervals along a circle having a constant radius in the center of the cylindrical chamber.

In an exemplary embodiment of the present invention, the plasma processing method may further include providing a single third plasma source disposed in the center of the chamber to receive a third gas. The third gas may include at least one of the first gas, the second gas, an inert gas, and a nitrogen gas.

In an exemplary embodiment of the present invention, at least one of the first and second plasma sources may operate in a pulse mode.

In an exemplary embodiment of the present invention, the plasma processing method may further include distributing power of the first RF power source to the first plasma sources using a first distribution unit; and distributing power of the second RF power source to the second plasma sources using a second power distribution unit. The first power distribution unit may include a first conductive outer cover covering the first power distribution line and being grounded; and first ground lines of the same length each having one end connected to the first conductive outer cover and the other end connected to a first group antenna. Distances between an input terminal of the first power distribution unit and the first group antennas may be equal to each other. The second power distribution unit may include a second power distribution line; a second conductive outer cover covering the second power distribution line and being grounded; and second ground lines of the same length each having one end connected to the second conductive outer cover and the other end connected to the second group antenna. Distances between an input terminal of the second power distribution unit and the second group antennas may be equal to each other.

A substrate processing apparatus according to an embodiment of the present invention may include one or more first plasma sources mounted on a chamber to receive a first gas; one or more second plasma sources mounted on the chamber to receive a second gas; a first RF power source supplying power to the first plasma sources; a second RF power source supplying power to the second plasma sources; a first power distribution unit distributing the power received from the first RF power source to the first plasma sources; a second power distribution unit distributing the power received from the second RF power source to the second plasma sources; and an RF bias power source applying RF power to a substrate disposed inside the chamber.

In an exemplary embodiment of the present invention, the first gas may be an etching gas decomposed to etch the substrate, and the second gas may be a deposition gas decomposed to generate polymer.

In an exemplary embodiment of the present invention, each of the first plasma sources may include a first group dielectric substance mounted in a first group through-hole formed at the chamber; first gas supply means for supplying a first gas around the first group dielectric substance; and first group antennas for generation of first plasma disposed around the first group dielectric substance. The first group antennas may be electrically connected in parallel. Each of the second plasma sources may include a second group dielectric substance mounted in a second group through-hole formed at the chamber; second gas supply means for supplying a second gas around the second group dielectric substance; and second group antennas for generation of second plasma disposed around the second group dielectric substance. The second group antennas may be electrically connected in parallel.

In an exemplary embodiment of the present invention, the first power distribution unit may include a first conductive outer cover covering the first power distribution line and being grounded; and first ground lines of the same length each having one end connected to the first conductive outer cover and the other end connected to a first group antenna. Distances between an input terminal of the first power distribution unit and the first group antennas may be equal to each other. The second power distribution unit may include a second power distribution line; a second conductive outer cover covering the second power distribution line and being grounded; and second ground lines of the same length each having one end connected to the second conductive outer cover and the other end connected to the second group antenna. Distances between an input terminal of the second power distribution unit and the second group antennas may be equal to each other.

In an exemplary embodiment of the present invention, the first plasma sources may be disposed at regular intervals along a circle having a constant radius in the center of the cylindrical chamber. The second plasma sources may be disposed between the first plasma sources at regular intervals along a circle having a constant radius in the center of the cylindrical chamber.

In an exemplary embodiment of the present invention, the first power distribution unit may include an input branch in the form of a coaxial cable to receive power from the first RF power source; and a three-way branch connected to the input branch and in the form of a coaxial cable branching out three ways. The second power distribution unit may include an input branch in the form of a coaxial cable to receive power from the second RF power source; and a three-way branch connected to the input branch and in the form of a coaxial cable branching out three ways.

In an exemplary embodiment of the present invention, the first RF power source and the second RF power source may be synchronized with each other to operate in a pulse mode and provide outputs at different times.

In an exemplary embodiment of the present invention, the substrate processing apparatus may further include a single third plasma source disposed in the center of the chamber to receive a third gas; and a third RF power source supplying power to the third plasma source. The third gas may include at least one of the first gas, the second gas, an inert gas, and a nitrogen gas.

### BRIEF DESCRIPTION OF THE DRAWINGS

The present invention will become more apparent in view of the attached drawings and accompanying detailed description. The embodiments depicted therein are provided by way of example, not by way of limitation, wherein like reference numerals refer to the same or similar elements. The drawings are not necessarily to scale, emphasis instead being placed upon illustrating aspects of the present invention.

FIG. 1 is a top plan view of a plasma generating apparatus according to an embodiment of the present invention.

FIG. 2 is a cross-sectional view of the plasma generating apparatus in FIG. 1 during an etch cycle.

FIG. 3 is a cross-sectional view of the plasma generating apparatus in FIG. 1 during a deposition cycle.

FIG. 4 illustrates electrical connection of the plasma generating apparatus in FIG. 1.

FIG. 5 is a cross-sectional view of a plasma source of the plasma generating apparatus in FIG. 1.

FIG. 6A is a perspective view of a power distribution unit of the plasma generating apparatus in FIG. 1.

FIG. 6B is a cross-sectional view taken along the line I-I′ in FIG. 6A.

FIG. 6C is a cross-sectional view taken along the line II-II′ in FIG. 6A.

FIG. 7 is a top plan view of a magnet of a plasma generating apparatus in FIG. 1.

FIG. 8A is a cross-sectional view of a plasma generating apparatus according to another embodiment of the present invention.

FIGS. 8B and 8C are top plan views illustrating an etching operation and a deposition apparatus of the plasma generating apparatus in FIG. 8A.

FIG. 8D is a timing diagram of the plasma generating apparatus in FIG. 8A.

FIGS. 9 to 11 are cross-sectional views of plasma sources according to other embodiments of the present invention.

FIG. 12 illustrates a power distribution method according to another embodiment of the present invention.

FIG. 13 is a top plan view of a substrate processing apparatus according to another embodiment of the present invention.

FIG. 14 illustrates power distribution of the substrate processing apparatus in FIG. 13.

### DETAILED DESCRIPTION

A vertical channel flash memory device includes a stack where a conductive layer such as polysilicon and an insulating layer such as oxide are alternately stacked. The alternately stacked conductive and insulating layers are etched to form a hole for a channel, and a conductive material for a channel fills the hole for a channel. A very high aspect ratio makes it difficult to form the hole for a channel. In order to form the hole for a channel, it is necessary to suitably maintain etching and deposition.

A stacked-type semiconductor memory device where memory chips are three-dimensionally stacked using through-electrodes as communication means has been developed for high-speed communication between semiconductor integrated circuits. In the stacked-type semiconductor device, memory chips are electrically connected by forming a through silicon via (hereinafter referred to as “TSV”) hole and a TSV to fill the TSV hole. Since an aspect ratio of a TSV hole is very high, it is difficult to form the TSV hole. During a process of forming the TSV hole, the shape of the hole is collapsed when an etching process is excessive and the hole is blocked when a deposition process is excessive. Therefore, during the process of forming the hole, it is necessary to suitably maintain the deposition process and the etching process. For example, one method may be that an etching process is performed using an etching gas for predetermined time, a small amount of deposition process is performed using a deposition gas on a sidewall of an etched hole, and the etching process is re-performed using the etching gas. These processes may be repeated to form a hole in the shape of a pillar having a constant diameter.

That is, such a Bosch process requires periodical change depending on time of a process gas to form a TSV hole. However, it is difficult to practically apply the periodical change depending on time of a process because a lot of time is required for the periodical change. In addition, an etch rate of conventional inductively coupled plasma is significantly low for TSV hole etching.

To overcome the above disadvantages, in a method of forming a hole according to an embodiment of the present invention, a first gas such as SF₆ mainly contributed to etching and a second gas such as C₄F₈ mainly contributed to polymer deposition are always supplied into a chamber. However, the first gas and the second gas are supplied while being spatially spaced apart from each other and plasma generating apparatuses are disposed in a region to which the first gas is supplied and a region to which the second gas is supplied, respectively. When an etching process is desired to be performed, plasma discharge is performed using the plasma generating apparatus disposed in the region to which the first gas is supplied. Generated plasma and radical such as fluorine (F) are supplied to a substrate to form an etching process.

Afterwards, when a deposition process is desired to be performed, plasma discharge is performed using the plasma generating apparatus disposed in the region to which the second gas is supplied. Generated plasma and polymer are supplied to the substrate to perform a protection layer deposition process on a sidewall.

Therefore, the etching process and the deposition process may be performed by operating the corresponding plasma generating apparatuses, respectively. That is, since operation switching speed of the plasma generating apparatus for etching and the plasma generating apparatus for deposition are very high, change from the deposition process to the etching process is very fast. Thus, a hole of desired shape may be formed and a shape of scallop may be adjusted. In order to increase a deposition rate, the plasma generating apparatus may be an inductively coupled plasma apparatus using a magnetic field. Right-handed circularly polarized wave (R-Wave) may travels into plasma from magnetized inductively coupled plasma. Accordingly, a plasma density may increase.

A plurality of plasma generating apparatuses for etching may be provided to improve process uniformity. In addition, a plurality of plasma generating apparatuses for deposition may be provided to improve process uniformity. The plasma generating apparatuses may be electrically connected in parallel to decrease the number of RF power sources.

For example, by supplying power to a plasmas generating apparatus for etching, a first gas such as SF₆ mainly generates etching plasma and a radical such as fluorine (F). The generated etching plasma and fluorine (F) are diffused to be supplied to a substrate. Thus, an etching process is performed on the substrate. A second gas such as C₄F₈ may continue to be supplied into a chamber during an etching process. However, the second gas such as C₄F₈ is not directly supplied to the plasma generating apparatus for etching. Therefore, since the second gas such as C₄F₈ is not nearly deposited, a deposition process is not nearly performed.

Afterward, the power supplied to the plasma generating apparatus for etching is cut off. By supplying power to the plasma generating apparatus for deposition, the second gas such as C₄F₆ mainly generates deposition plasma and polymer. The generated deposition plasma and polymer are diffused to be supplied to the substrate. Thus, a protection layer deposition process is performed on the substrate. The foregoing etching and deposition may be repeated to form a TSV hole.

The present invention will now be described more fully hereinafter with reference to the accompanying drawings, in which embodiments of the present invention are shown. The present invention may, however, be embodied in many different forms and should not be construed as limited to the embodiments set forth herein. Rather, these embodiments are provided so that this disclosure will be thorough and complete, and will fully convey the scope of the present invention to those skilled in the art. Like reference numerals refer to like elements throughout.

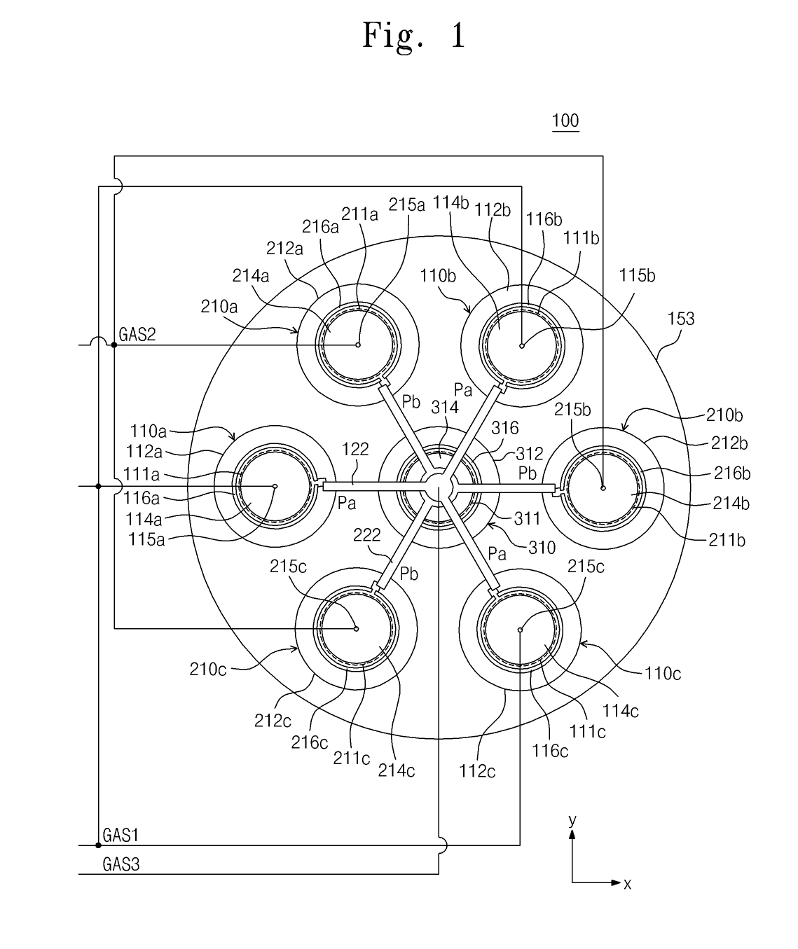

FIG. 1 is a top plan view of a plasma generating apparatus according to an embodiment of the present invention.

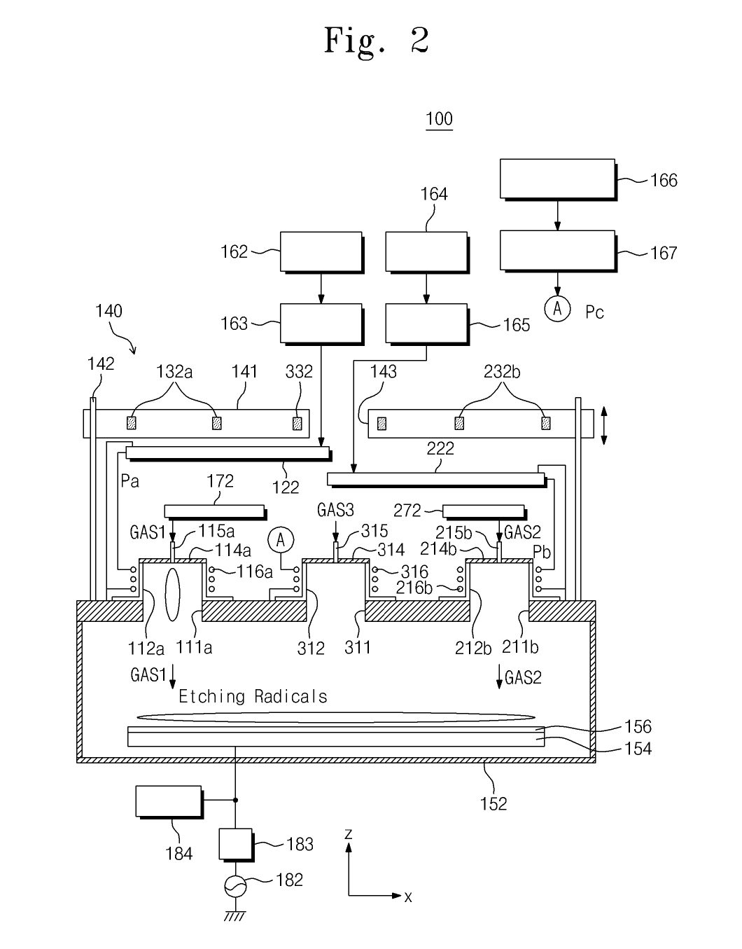

FIG. 2 is a cross-sectional view of the plasma generating apparatus in FIG. 1 during an etch cycle.

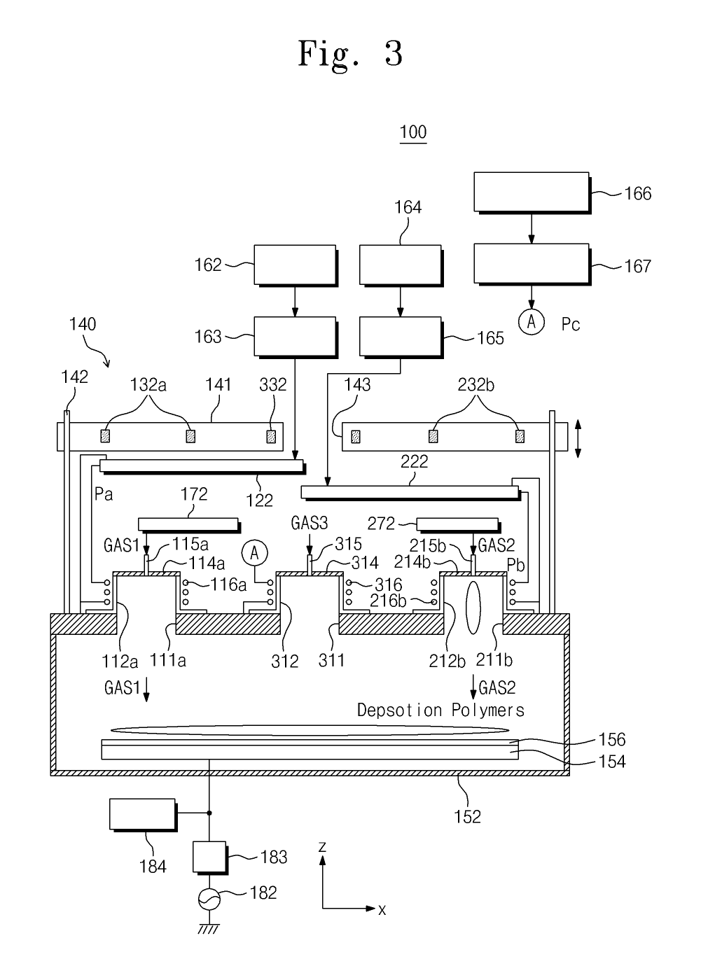

FIG. 3 is a cross-sectional view of the plasma generating apparatus in FIG. 1 during a deposition cycle.

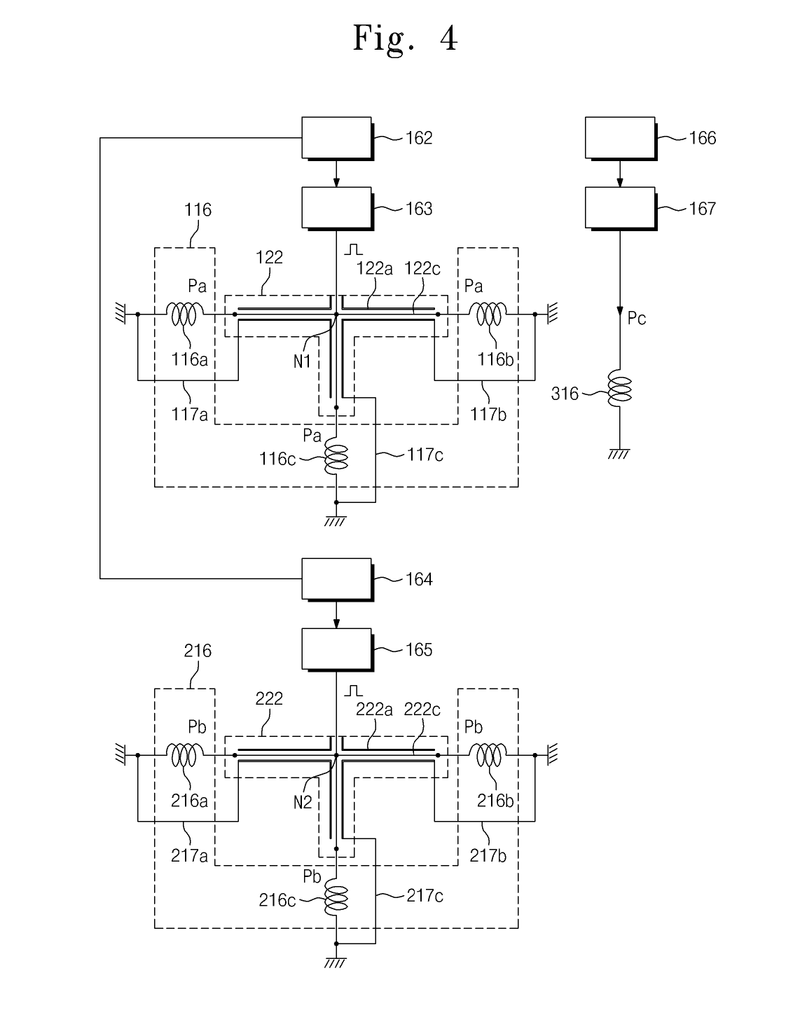

FIG. 4 illustrates electrical connection of the plasma generating apparatus in FIG. 1.

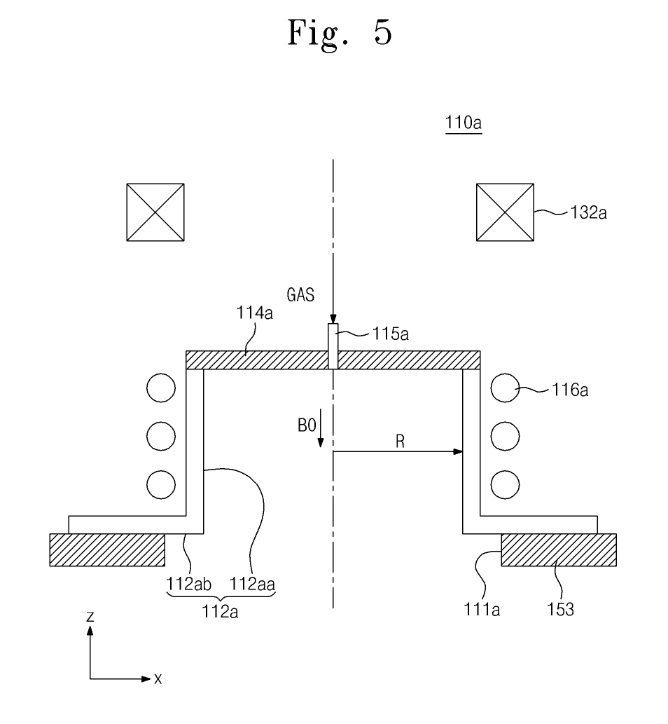

FIG. 5 is a cross-sectional view of a plasma source of the plasma generating apparatus in FIG. 1.

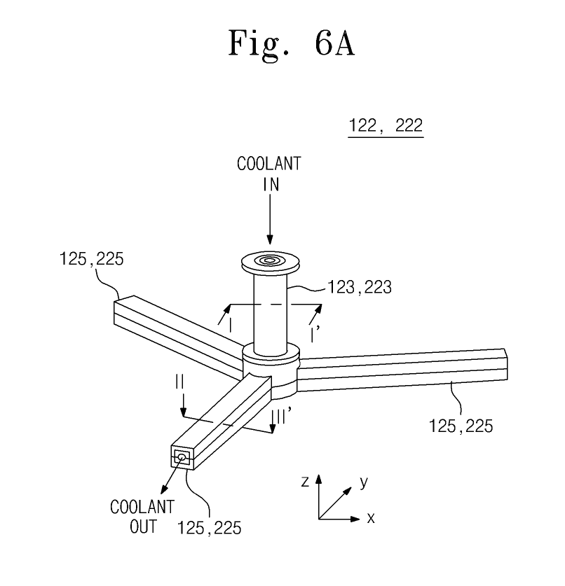

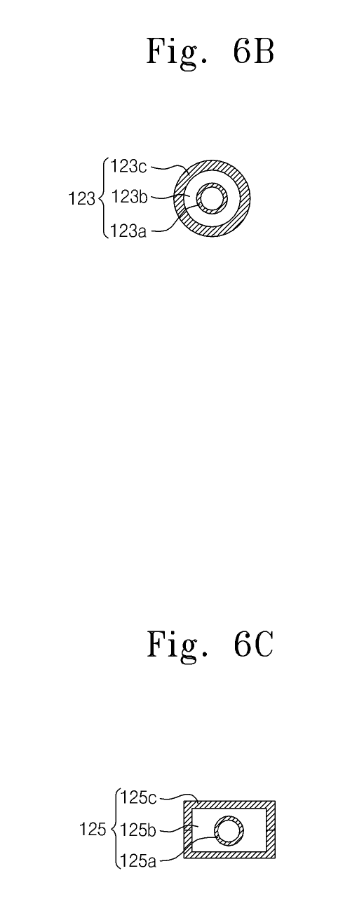

FIG. 6A is a perspective view of a power distribution unit of the plasma generating apparatus in FIG. 1, FIG. 6B is a cross-sectional view taken along the line I-I′ in FIG. 6A, and FIG. 6C is a cross-sectional view taken along the line II-II′ in FIG. 6A.

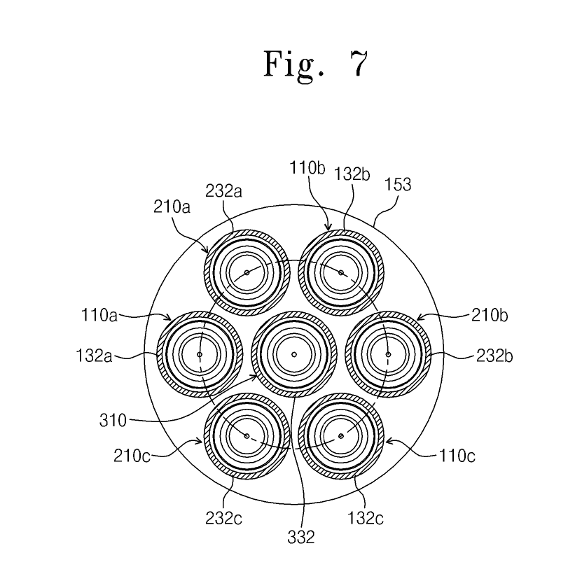

FIG. 7 is a top plan view of a magnet of a plasma generating apparatus in FIG. 1.

Referring to FIGS. 1 to 7, a substrate processing apparatus 100 includes one or more first plasma sources 110a, 110b, and 110c mounted on a chamber 152 to receive a first gas, one or more second plasma sources 210a, 210b, and 210c mounted on the chamber 152 to receive a second gas, a first RF power source 162 supplying power to the first plasma sources 110a, 110b, and 110c, a second RF power source 164 supplying power to the second plasma sources 210a, 210b, and 210c, a first power distribution unit 122 distributing the power received from the first RF power source 162 to the first plasma sources 110a, 11b, and 110c, a second power distribution unit 222 distributing the power received from the second RF power source 164 to the second plasma sources 210a, 210b, and 210c, and an RF bias power source 182 applying RF power to a substrate 156 disposed inside the chamber 152.

The chamber 152 may be in the form of a cylinder or a square container. The chamber 152 may include an exhaust part (not shown). The chamber 152 may include a substrate holder 154 and a substrate 156 mounted on the substrate holder 154. The chamber 152 may include a top plate 153. The top plate 153 may be a lid of the chamber 152. The top plate 153 may be made of a metal or a metal alloy. The top plate 153 may be disposed on an x-y plane.

The substrate holder 154 may include a temperature control unit (not shown). The temperature control unit may control a temperature of the substrate 156. The temperature control unit may cool or heat the substrate 156 with in a temperature between −150 and 750 degrees centigrade.

The RF bias power source 182 may supply RF power to the substrate holder 154 through an RF bias matching network 183. Thus, plasma may be generated on the substrate 156 and the plasma may provide energy to the substrate 156 with a self-bias. A DC bias power source 184 may be connected to the substrate holder 154.

The first gas may be an etching gas decomposed by plasma to etch a substrate, and the second gas may be a deposition gas decomposed by plasma to generate polymer. For example, the first gas may include at least one of a fluorine-containing gas and a chlorine-containing gas. The second gas may include at least one of an oxygen gas, a hydrogen gas, and a carbon-containing gas. More specifically, the first gas may include at least one of SF₆, CF₄, and CHF₃. The second gas may include at least one of C₄F₈, C₃F₆, C₂F₂, oxygen, and hydrogen.

The first gas may always be supplied to the first plasma sources 110a, 110b, and 110c, and the second gas may always be supplied to the second plasma sources 210a, 210b, and 210c. Gas exchange may be eliminated to reduce process time.

The first gas may be decomposed by the first plasma sources 110a, 110b, and 110c to etch the substrate 156. The second gas may be decomposed by the second plasma sources 210a, 210b, and 210c to deposit polymer on the substrate 156. That is, the first plasma sources 110a, 110b, and 110c and the second plasma sources 210a, 210b, and 210c may be alternated to generate plasma.

The first plasma sources 110a, 11b, and 110c may be disposed on the top plate 153 of the cylindrical chamber 152 along a circumference having a constant radius at regular intervals. The second plasma sources 210a, 210b, and 210c may be disposed on the top plate 153 of the cylindrical chamber 152 along a circumference having a constant radius at regular intervals.

First group through-holes 111a, 111b, and 111c may be symmetrical about the circumference having a constant radius on the basis of the center of the top plate 153. Second group through-holes 211a, 211b, and 211c may be symmetrical about the circumference having a constant radius on the basis of the center of the top plate 153 and may be disposed between a pair of adjacent first group through-holes 111a, 111b, and 11c. The first plasma sources 110a, 110b, and 110c may be mounted in the first group through-holes 111a, 111b, and 11c, respectively. The second plasma sources 210a, 210b, and 210c may be mounted in the second group through-holes 211a, 211b, and 211c, respectively.

The first plasma sources 110a, 110b, and 110c may be electrically connected in parallel and may receive RF power from a single first RF power source 162. The second plasma sources 210a, 210b, and 210c may be electrically connected in parallel and may receive RF power from a single second RF power source 164. A frequency of the first RF power source 162 may be different from that of the second RF power source 164. Thus, mutual interference between the first RF power source 162 and the second RF power source 164 may be suppressed. The first plasma sources 110a, 110b, and 110c may have the same shape and the same structure.

The first plasma sources 110a, 110b, and 110c may include first group dielectric substances 112a, 112b, and 112c mounted in first group through-holes 111a, 111b, and 11c formed at the chamber 152, first gas supply means 115a, 115b, and 115c supplying a first gas around the first group dielectric substances 112a, 112b, and 112c, and first group antennas 116a, 116b, and 116c for generation of first plasma disposed around the first group dielectric substances 112a, 112b, and 112c, respectively. The first group antennas 116a, 116b, and 116c may be electrically connected in parallel.

The first group through-holes 111a, 111b, and 111c may be symmetrical about a circumference having a constant radius on the basis of the top plate 153. The first group dielectric substance 112a may include a tube body 112aa and a base 112ab. The base 112ab may be disposed on the first group through-hole 111a. The base 112ab may be combined with one end of the tube body 112aa, and a metal plate 114a may be disposed on the other end of the tube body 112aa. The first group dielectric substance 112a may be alumina, sapphire, quartz or ceramic. The first gas supply means 115a may be disposed in the center of the metal plate 114a. The first group antenna 116a may be disposed to cover the tube body 112aa. Each of the first group antennas 116a, 116b, and 116c may be a three-turn antenna. First magnets 132a, 132b, and 132c may be disposed to be vertically spaced apart from the first group antennas 116a, 116b, and 116c, respectively.

Each of the first magnets 132a, 132b, and 132c may be a permanent magnet or an electromagnet. The permanent magnet may have a toroidal shape and may be magnetized to establish a magnetic field in the central axis direction of a tube. The magnitude of the magnetic field established by the magnet in the center of the first group antenna may be between tens of Gausses and hundreds of Gausses. The magnetic field may allow a right-handed circularly polarized wave (R-wave) to penetrate plasma. Thus, plasma density may be higher than density of conventional inductively coupled plasma.

The second plasma sources 210a, 210b, and 210c may include second group dielectric substances 212a, 212b, and 212c mounted in second group through-holes 211a, 211b, and 211c formed at the chamber 152, second gas supply means 215a, 215b, and 215c supplying a second gas around the second group dielectric substances 212a, 212b, and 212c, and second group antennas 216a, 216b, and 216c for generation of second plasma disposed around the second group dielectric substances 212a, 212b, and 212c, respectively. The second group antennas 216a, 216b, and 216c may be electrically connected in parallel. The second plasma sources 210a, 210b, and 210c may have the same shape and the same structure.

The second group through-holes 211a, 211b, and 211c may be symmetrical about a circumference having a constant radius on the basis of the top plate 153. Each of the second group dielectric substances 212a, 212b, and 212c may include a tube body and a base. The base may be disposed on the second group through-holes 211a, 211b, and 211c. The base may be combined with one end of the tube body, and a metal plate may be disposed on the other end of the tube body. Second gas supply means 215a, 215b, and 215c may be disposed in the center of the metal plate. Second group antennas 216a, 216b, and 216c may be disposed to cover the tube body. Second magnets 232a, 232b, and 232c may be disposed to be vertically spaced apart from the second group antennas 216a, 216b, and 216c, respectively. Each of the second magnets 232a, 232b, and 232c may be a permanent magnet or an electromagnet. The permanent magnet may have a toroidal shape and may be magnetized in the central axis direction of the tube to establish a magnetic field in the central axis direction of a tube.

A third plasma source 310 may be disposed in the center of the top plate 153. A third gas may be supplied to the third plasma source 310 to generate plasma. The third gas may be the first gas, the second gas, an inert gas or a nitrogen gas. For example, when the third gas is the first gas, the third gas may always be supplied through the third plasma source 310.

For example, when the third gas is the first gas, the third gas may always be supplied through the third plasma source 310. In addition, the third plasma source 310 may operate simultaneously with the first plasma sources in synchronization with the first plasma sources.

For example, when the third gas is the second gas, the third gas may always be supplied through the third plasma source 310. The third plasma source may operate simultaneously with the second plasma sources in synchronization with the second plasma sources.

For example, when the third gas an inert gas, the third gas may always be supplied through the third plasma source 310. The third plasma source 310 may always operate independently of the first plasma sources or the second plasma sources. Thus, the third plasma source 310 may provide initial discharge to first plasma sources operating in a pulse mode and second plasma sources operating in a pulse mode.

The third plasma source 310 may include a third group dielectric substance 312 mounted in a third group through-hole formed at the chamber 152, third gas supply means 315 supplying a third gas around the third group dielectric substance 312, and a third group antenna 316 for generation of third plasma disposed around the third group dielectric substance 312. The third group antenna 316 may include a single antenna. A third magnet 332 may be disposed to be spaced apart from the third group antenna 316 in the z-axis direction. A third RF power source 166 supplies power to the third group antenna 316. A frequency of the third RF power source 166 may be different from a frequency of the first RF power source 162 and a frequency of the second RF power source 164. The third RF power source 166 may supply power to the third group antenna 316 through a third impedance matching network 167.

The first RF power source 162 may supply power to the first group antennas 116a, 116b, and 116c through the first power distribution unit 122. A first impedance matching network 163 is disposed between the first RF power source 162 and the first power distribution unit 122 to transfer maximum power to a load.

The second RF power source 164 supplies power to the second group antennas 216a, 216b, and 216c through the second power distribution unit 222. The second impedance matching network 165 is disposed between the second RF power source and the second power distribution unit 222 to transfer maximum power to a load. The first RF power source 162 supplies power at different time in synchronization with the second RF power source 164. That is, the second RF power source 164 may not supply power while the first RF power source 162 supplies power, and the first RF power source 162 may not supply power while the second RF power source 164 supplies power.

Conventionally, when power is distributed to an antenna connected in parallel to an inductively coupled antenna, the power is mainly supplied to a specific antenna and the power supplied to the other antennas is relatively low. Therefore, it is difficult to generate spatially uniform plasma.

In order to overcome the above disadvantage, the first power distribution unit 122 includes a first power distribution line 122a, a first conductive outer cover 122c covering the first power distribution line 122a and being grounded, and first ground lines 117a, 117b, and 117c each having one end connected to the first conductive outer cover 122c and the other end connected to each of the first group antennas 116a, 116b, and 116c. Distances between an input terminal N1 of the first power distribution unit 122 and the first group antennas 116a, 116b, and 116c may be equal to each other. In addition, the first ground lines 117a, 117b, and 117c have the same length. Thus, the first power distribution unit 122 may distribute equal power to all the first group antennas 116a, 116b, and 116c. That is, the first power distribution unit 122 may supply the same impedance to all the first group antennas 116a, 116b, and 116c.

The first power distribution unit 122 may include an input branch 123 in the form of a coaxial cable to receive power from the first RF power source 162 and a three-way branch 125 connected to the input branch 123 and in the form of a coaxial cable branching out three ways. The input branch 123 includes a central conductor 123, an insulator 123b covering the central conductor 123a, and a conductive outer cover 123 covering the insulator 123b. The central conductor 123a may be in the form of a pipe through which a coolant flows.

One end of the three-way branch 125 is connected to the input branch 123, and the other end thereof is connected to one end of each of the first group antennas 116a, 116b, and 116c. The three-way branch 125 includes three output branches each including a central conductor 125a, an insulator 152b covering the central conductor 125a, and a conductive outer cover 125c covering the insulator 125b. The central conductor 125a may be in the form of a pipe through which a coolant flows. One end of each of the first ground lines 117a, 117b, and 117c may be connected to the other end of each of the first group antennas 116a, 116b, and 116c, and the other end of each of the first ground lines 117a, 117b, and 117c may be connected to the other end of the conductive outer cover 125c of the output branch.

Specifically, when the first ground lines 117a, 117b, and 117c do not exist, power of the first RF power source 162 may be mainly supplied to a specific antenna. The first ground lines 117a, 117b, and 117c allow impedances of all the first group antennas 116a, 116b, and 116c to be kept evenly and thus provide even distribution of power. One end of each of the first ground lines 117a, 117b, and 117c may be connected to the top plate 153.

The second power distribution unit 222 may include a second power distribution line 222a, a second conductive outer cover 222c covering the second power distribution line 222a and being grounded, and second ground lines 217a, 217b, and 217c each having one end connected to the second conductive outer cover 222a and the other end connected to each of the second group antennas 216a, 216b, and 216c. Distances between an input terminal N2 of the second power distribution unit 222 and the second group antennas 216a, 216b, and 216c may be equal to each other.

The second power distribution unit 222 may include an input branch 223 in the form of a coaxial cable to receive power from the second RF power source 166 and a three-way branch 225 connected to the input branch 223 and in the form of a coaxial cable branching out three ways. The first power distribution unit 122 may be disposed on the second power distribution unit 222.

When the second ground lines 217a, 217b, and 217c do not exist, power of the second RF power source 164 may be mainly supplied to a specific antenna. The second ground lines 217a, 217b, and 217c allow impedances of all the second group antennas 216a, 216b, and 216c to be kept evenly and thus provide even distribution of power. One end of each of the second ground lines 217a, 217b, and 217c may be connected to the top plate 153.

A first gas distribution unit (not shown) may supply a first gas to the first plasma sources 110a, 110b, and 110c. A second gas distribution unit (not shown) may supply a second gas to the second plasma sources 210a, 210b, and 210c.

First magnets 132a, 132b, and 132c, second magnets 232a, 232b, and 232c, and a third magnet 332 may each have a donut shape or a toroidal shape. Cross sections of the first magnets 132a, 132b, and 132c, the second magnets 232a, 232b, and 232c, and the third magnet 332 may each be in the form of a square or a circle.

The first magnets 132a, 132b, and 132c, the second magnets 232a, 232b, and 232c, and the third magnet 332 may be inserted into a magnet fixing plate 141. The first magnets 132a, 132b, and 132c, the second magnets 232a, 232b, and 232c, and the third magnet 332 may be disposed to be spaced apart from the center of an antenna in the z-axis direction.

A moving part 140 may be fixedly combined with the top plate 153. The moving part 140 may include at least one support pillar 142 extending perpendicularly to a plane (xy plane) on which the dielectric tubes are disposed. The magnet fixing plate 141 may be inserted into the support pillar 142 to be movable along the support pillar 142. A through-hole 143 may be formed in the center of the magnet fixing plate 141.

According to a modified embodiment of the present invention, the third plasma source 310 may be removed.

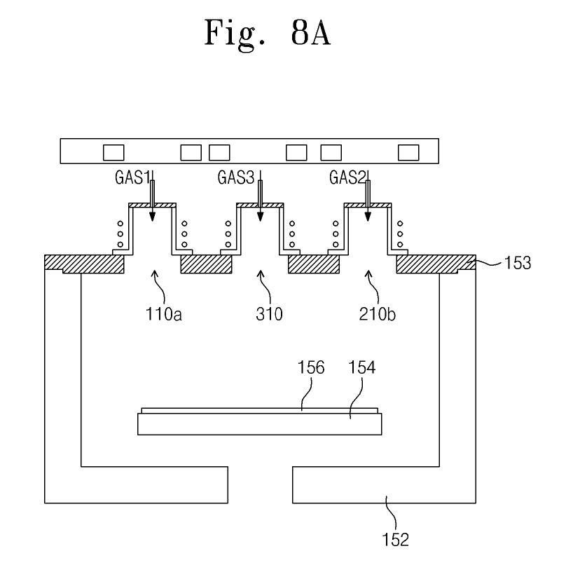

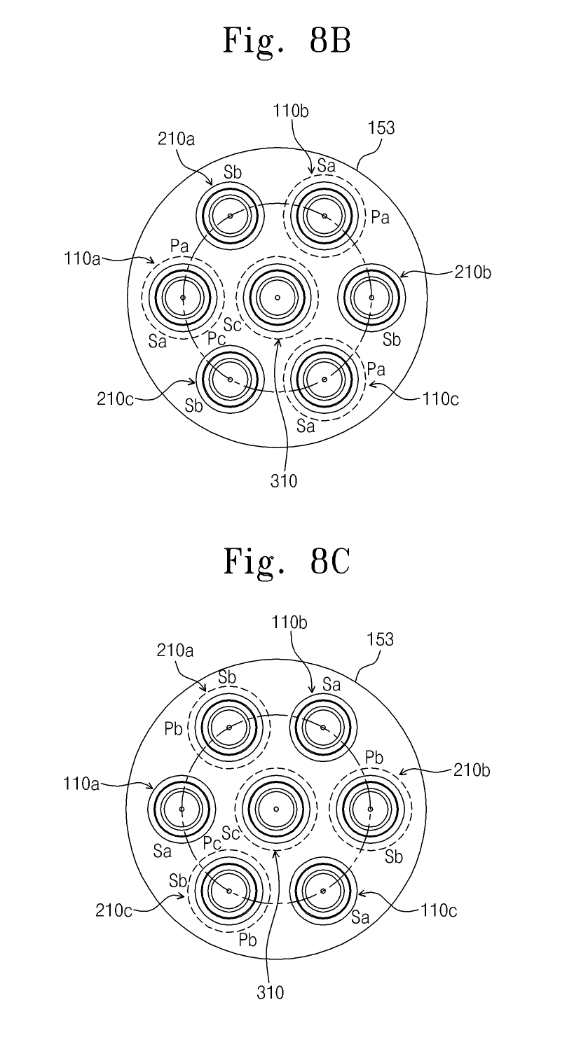

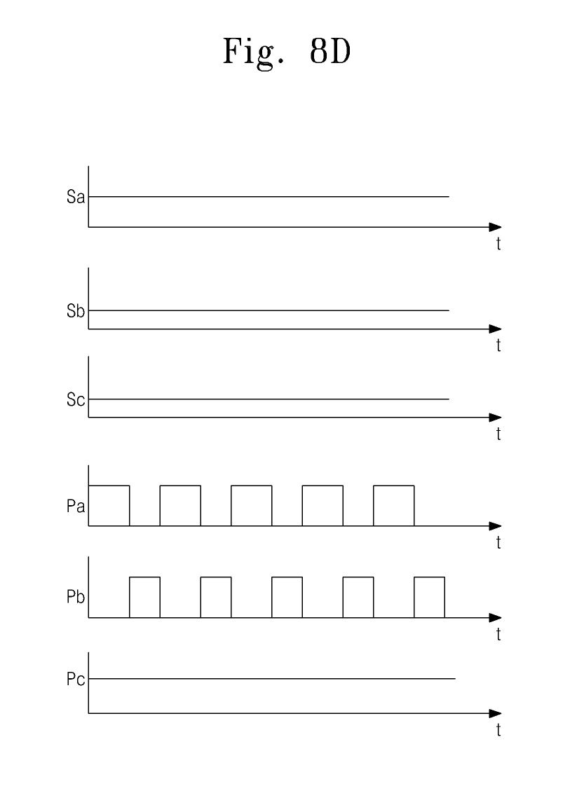

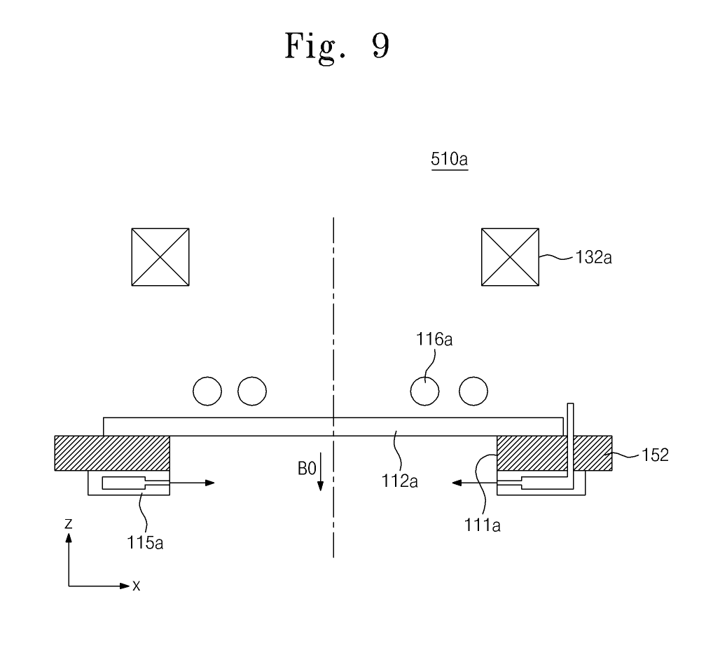

FIG. 8A is a cross-sectional view of a plasma generating apparatus according to another embodiment of the present invention.

FIGS. 8B and 8C are top plan views illustrating an etching operation and a deposition apparatus of the plasma generating apparatus in FIG. 8A.

FIG. 8D is a timing diagram of the plasma generating apparatus in FIG. 8A.

Referring to FIGS. 1 to 8D, a plasma processing method includes mounting one or more first plasma sources 110a, 110b, and 110c and one or more second plasma sources 210a, 210b, and 210c on a chamber, supplying a first gas to the first plasma sources 110a, 110b, and 110c, supplying a second gas different from the first gas to the second plasma sources 210a, 210b, and 210c, applying power to the first plasma sources 110a, 110b, and 110c to generate first plasma, applying power to the second plasma sources 210a, 210b, and 210c to generate second plasma, and processing a substrate 156 disposed inside the chamber using the first plasma and the second plasma.

A hole may be formed at the substrate 156 during the step of processing the substrate 156 disposed inside the chamber using the first plasma and the second plasma.

The first plasma and the second plasma may be alternately generated.

The first gas may include at least one of a fluorine-containing gas and a chlorine-containing gas, and the second gas may include at least one of an oxygen gas, a hydrogen gas, and a carbon-containing gas.

The first gas may include at least one of SF₆, CF₄, and CHF₃. The second gas may include at least one of C₄F₈, C₃F₆, C₂F₂, oxygen, and hydrogen.

The first plasma sources 110a, 110b, and 110c are disposed at regular intervals along a circle having a constant radius in the center of the cylindrical chamber 152, and the second plasma sources 210a, 210b, and 210c are disposed between the first plasma sources 110a, 110b, and 110c at regular intervals along a circle having a constant radius in the center of the chamber 152.

A single third plasma source 310 may be additionally disposed in the center of the chamber 152 to receive a third gas. The third gas may include at least one of the first gas, the second gas, an inert gas, and a nitrogen gas.

At least one of the first plasma source 110a, 110b, and 110c and the second plasma sources 210a, 210b, and 210c may operate in a pulse mode. Each of the first plasma source 110a, 110b, and 110c and the second plasma sources 210a, 210b, and 210c may be an inductively coupled plasma source using a magnetic field.

In FIG. 8D, Sa represents a flow rate of the first gas supplied to the first plasma sources 110a, 110b, and 110c, Sb represents a flow rate of the second gas supplied to the second plasma sources 210a, 210b, and 210c, and Sc represents a flow rate of the third gas supplied to the third plasma source 310. The first gas, the second gas, and the third gas may be supplied to their plasma sources while having their constant flow rates, respectively.

Also in FIG. 8D, Pa represents power supplied to each of the first plasma sources 110a, 110b, and 110c, Pb represents power supplied to each of the second plasma sources 210a, 210b, and 210c, and Pc represents power supplied to the third plasma source 310. The first plasma sources 110a, 110b, and 110c may operate in a pulse mode with a period. The second plasma sources 210a, 210b, and 210c may operate in a pulse mode with a period. The third plasma source 310 may operate in a continuous mode. The first plasma sources 110a, 110b, and 110c and the second plasma sources 210a, 210b, and 210c may operate at different times. Accordingly, an etching gas may be supplied to the substrate 156 while the first plasma sources 110a, 110b, and 110c operate. Thereafter, a deposition gas may be supplied to the substrate 156 while the second plasma sources 210a, 210b, and 210c operate. Thus, a TVS hole etching process may be performed.

FIG. 9 is a cross-sectional view of a plasma source according to another embodiment of the present invention.

Referring to FIG. 9, a plasma source 510a may include a first group dielectric substance 112a mounted in a first group through-hole 111a formed at a chamber 152, first gas supply means 115a supplying a first gas around the first group dielectric substance 112a, and a first group antenna 116a for generation of first plasma disposed around the first group dielectric substance 112a. The first group dielectric substance 112a may be a disc-shaped dielectric substance, and the first group antenna 116 may be a spiral-type antenna. A first magnet 132a may be disposed to be spaced apart from the first group antenna 116 in the z-axis direction. The first gas supply means 115a may supply the first gas to a bottom surface of the first group through-hole 111a.

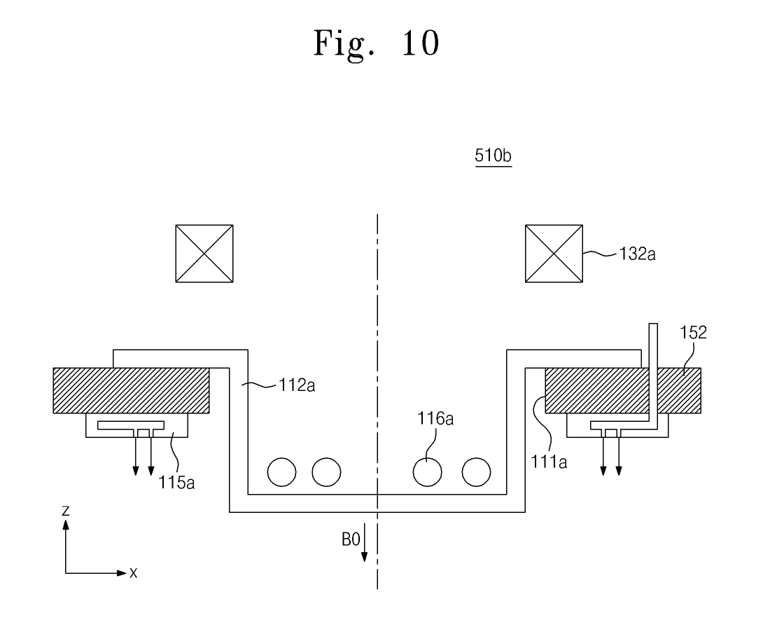

FIG. 10 is a cross-sectional view of a plasma source according to another embodiment of the present invention.

Referring to FIG. 10, a plasma source 510b may include a first group dielectric substance 112a mounted on a first group through-hole 111a formed at a chamber 152, first gas supply means 115a supplying a first gas to the first group dielectric substance 112a, and a first group antenna 116a for generation of first plasma disposed around the first group dielectric 112a. The first group dielectric substance 112a may be a bell-jar type dielectric substance, and the first group antenna 116 may be a spiral antenna. The first group dielectric substance 112a may be disposed to be partially inserted into the first group through-hole 111a.

A first magnet 132a may be disposed to be spaced apart from the first group antenna 116 in the z-axis direction. The first gas supply means 115a may supply the first gas to a bottom surface of the first group through-hole 111a.

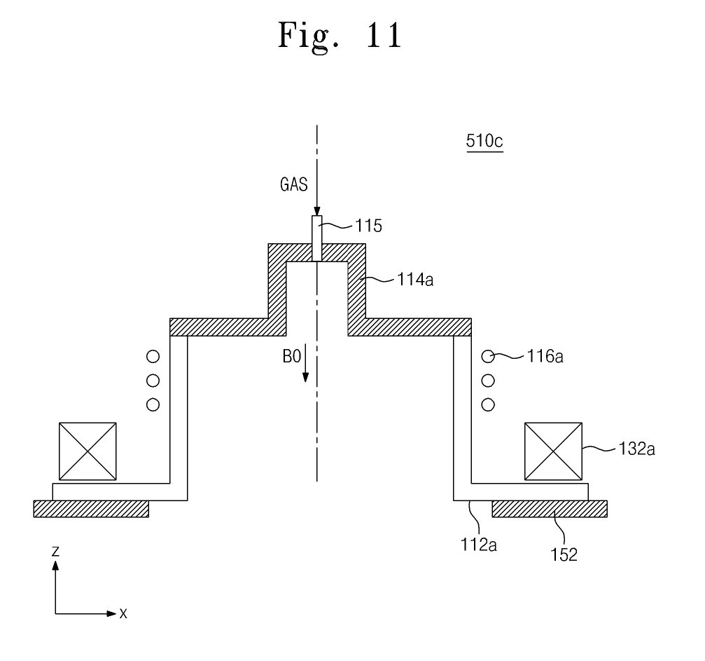

FIG. 11 is a cross-sectional view of a plasma source according to another embodiment of the present invention.

Referring to FIG. 11, a plasma source 510c may include a first group dielectric substance 112a mounted on a first group through-hole 111a formed at a chamber 152, first gas supply means 115 supplying a first gas to the first group dielectric substance 112a, and first group antennas 116a for generation of first plasma disposed around the first group dielectric 112a. The first group dielectric substance 112a may be a tube-type dielectric substance, and the first group antenna 116 may be a helical antenna. The first group dielectric substance 112a may be disposed to protrude from the chamber 152. The first group dielectric substance 112a may include a metallic lid 114a. The first gas supply means 115 may be disposed at the metallic lid 114a to supply the first gas. A first magnet 132a may be disposed to be spaced apart from the first group antennas 116a in the z-axis direction.

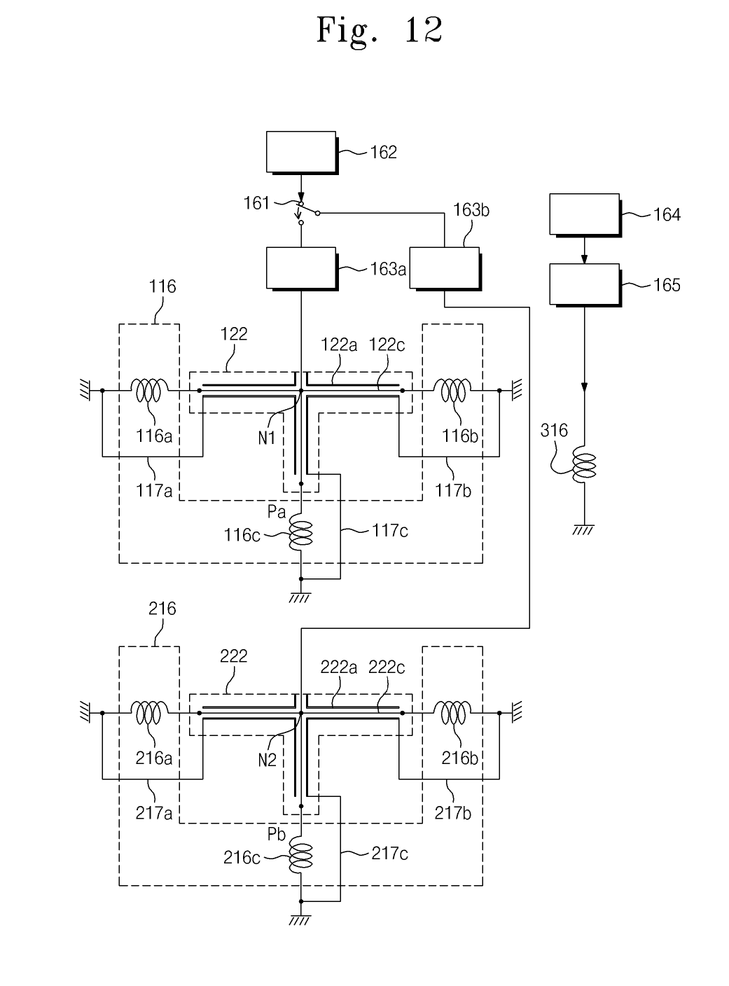

FIG. 12 illustrates a power distribution method according to another embodiment of the present invention. In FIG. 12, sections different from FIG. 4 will be extensively described to avoid duplicate description.

Referring to FIGS. 4 and 12, a first RF power source may selectively supply power to a first group antenna or second group antennas through a switch. A first impedance matching network may be disposed between the switch and the first group antenna, and a second impedance matching network may be disposed between the switch and the second group antenna. According to the operation of the switch, power of the first RF power source may be supplied to the first group antenna through the first impedance matching network and a first power distribution unit. Alternatively, the power of the first RF power source may be supplied to the second group antenna through the second impedance matching network and a second power distribution unit.

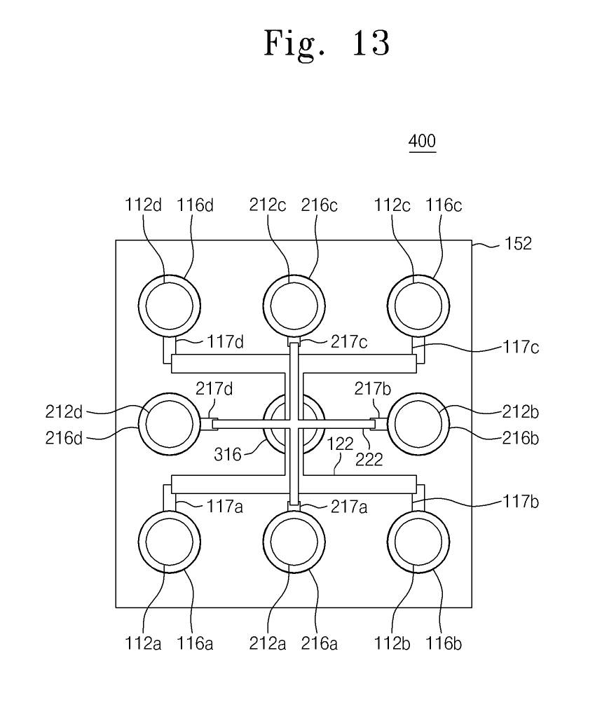

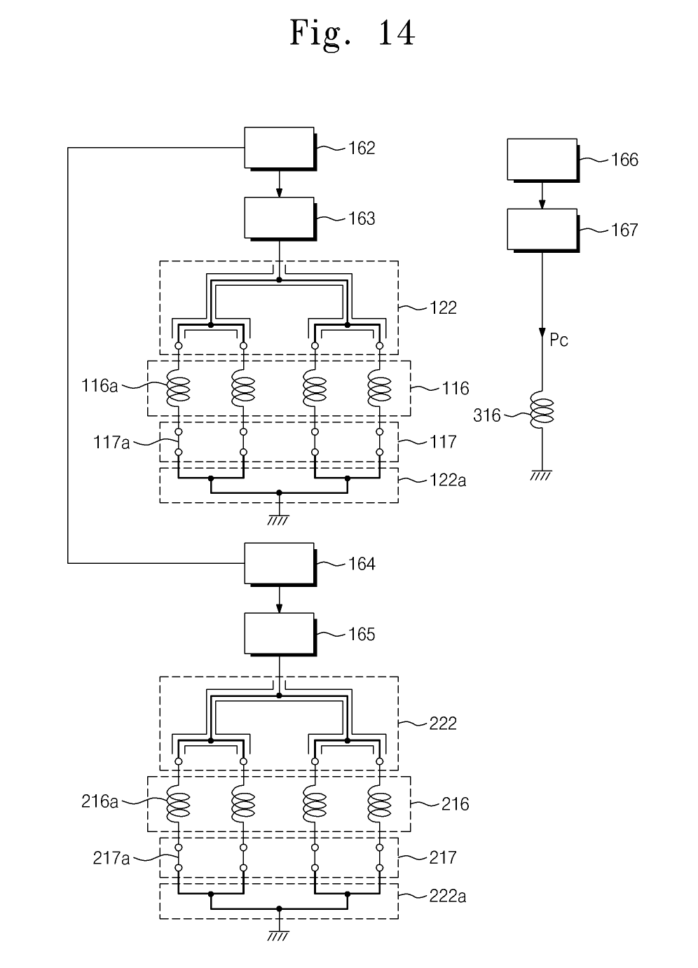

FIG. 13 is a top plan view of a substrate processing apparatus according to another embodiment of the present invention. FIG. 14 illustrates power distribution of the substrate processing apparatus in FIG. 13. In FIGS. 13 and 14, sections different from FIGS. 1 to 3 will be extensively described to avoid duplicate description.

Referring to FIGS. 13 and 14, a substrate processing apparatus 400 includes one or more first plasma sources 110a, 110b, 110c, and 110d mounted on a chamber 152 to receive a first gas, one or more second plasma sources 210a, 210b, 210c, and 210d mounted on the chamber 152 to receive a second gas different from the first gas, a first RF power source 162 supplying power to the first plasma sources 110a, 110b, 110c, and 110d, a second RF power source 164 supplying power to the second plasma sources 210a, 210b, 210c, and 210d, a first power distribution unit 122 distributing the power received from the first RF power source 162 to the first plasma sources 110a, 110b, 110c, and 110d, a second power distribution unit 222 distributing the power received from the second RF power source 164 to the second plasma sources 210a, 210b, 210c, and 210d, and an RF bias power source 182 applying RF power to a substrate disposed inside the chamber 152. The chamber 152 may be in the form of a square container.

A first ground line 117 may have the same length. If explained conceptually, a conductive outer cover 122a of the first power distribution unit 122 may be connected to the first ground line 117 to have a tree structure.

In addition, a second ground line 217 may have the same length. If explained conceptually, a conductive outer cover 222a of the second power distribution unit 222 may be connected to the second ground line 217 to have a tree structure.

According to above-described embodiments of the present invention, a substrate processing apparatus may form a through silicon via (TSV) hole with large-area uniformity and high processing speed.

Although the present invention has been described in connection with the embodiment of the present invention illustrated in the accompanying drawings, it is not limited thereto. It will be apparent to those skilled in the art that various substitutions, modifications and changes may be made without departing from the scope and spirit of the present invention.

What is claimed is:

1. A plasma processing method comprising:
mounting one or more first plasma sources and one or more second plasma sources on a chamber;
supplying a first gas to the first plasma sources;
supplying a second gas different from the first gas to the second plasma sources;
applying power to the first plasma sources to generate first plasma;
applying power to the second plasma sources to generate second plasma; and
processing a substrate disposed inside the chamber using the first plasma and the second plasma.

2. The plasma processing method of claim 1, wherein a hole is formed at the substrate during the step of processing the substrate disposed inside the chamber using the first plasma and the second plasma.

3. The plasma processing method of claim 1, wherein the first plasma and the second plasma are alternately generated.

4. The plasma processing method of claim 1, wherein the first gas includes at least one of a fluorine-containing gas and a chlorine-containing gas, and
wherein the second gas may include at least one of an oxygen gas, a hydrogen gas, and a carbon-containing gas.

5. The plasma processing method of claim 1, wherein the first gas includes at least one of SF₆, CF₄, and CHF₃, and
wherein the second gas includes at least one of C₄F₈, C₃F₆, C₂F₂, oxygen, and hydrogen.

6. The plasma processing method of claim 1, wherein each of the first and second plasma sources is an inductive coupled plasma source using a magnetic field.

7. The plasma processing method of claim 1, wherein each of the first plasma sources comprises:
a first group through-hole formed at the chamber;
a first group dielectric substance mounted in the first group through-hole;
first gas supply means for supplying the first gas around the first group dielectric substance; and
a first group antenna for generation of first plasma disposed around the first group dielectric substance, and
wherein each of the second plasma sources comprises:
a second group through-hole formed at the chamber;
a second group dielectric substance mounted in the second group through-hole;
second gas supply means for supplying the second gas around the second group dielectric substance; and
a second group antenna for generation of second plasma disposed around the second group dielectric substance.

8. The plasma processing method of claim 1, wherein the first group antenna is electrically connected to a first RF power source, and
wherein the second group antennal is electrically connected to a second RF power source.

9. The plasma processing method of claim 1, wherein the first plasma sources are disposed at regular intervals along a circle having a constant radius in the center of the cylindrical chamber, and
wherein the second plasma sources are disposed between the first plasma sources at regular intervals along a circle having a constant radius in the center of the cylindrical chamber.

10. The plasma processing method of claim 1, further comprising:
providing a single third plasma source disposed in the center of the chamber to receive a third gas,
wherein the third gas includes at least one of the first gas, the second gas, an inert gas, and a nitrogen gas.

11. The plasma processing method of claim 1, wherein at least one of the first and second plasma sources operates in a pulse mode.

12. The plasma processing method of claim 1, further comprising:
distributing power of the first RF power source to the first plasma sources using a first distribution unit; and
distributing power of the second RF power source to the second plasma sources using a second power distribution unit,
wherein the first power distribution unit comprises:
a first conductive outer cover covering the first power distribution line and being grounded; and
first ground lines of the same length each having one end connected to the first conductive outer cover and the other end connected to a first group antenna,
wherein distances between an input terminal of the first power distribution unit and the first group antennas are equal to each other,
wherein the second power distribution unit comprises:
a second power distribution line;
a second conductive outer cover covering the second power distribution line and being grounded; and
second ground lines of the same length each having one end connected to the second conductive outer cover and the other end connected to the second group antenna, and
wherein distances between an input terminal of the second power distribution unit and the second group antennas are equal to each other.

13. A substrate processing apparatus comprising:
one or more first plasma sources mounted on a chamber to receive a first gas;
one or more second plasma sources mounted on the chamber to receive a second gas;
a first RF power source supplying power to the first plasma sources;
a second RF power source supplying power to the second plasma sources;
a first power distribution unit distributing the power received from the first RF power source to the first plasma sources;
a second power distribution unit distributing the power received from the second RF power source to the second plasma sources; and
an RF bias power source applying RF power to a substrate disposed inside the chamber.

14. The substrate processing apparatus of claim 13, wherein the first gas is an etching gas decomposed to etch the substrate, and the second gas is a deposition gas decomposed to generate polymer.

15. The substrate processing apparatus of claim 13, wherein each of the first plasma sources comprises:
a first group dielectric substance mounted in a first group through-hole formed at the chamber;
first gas supply means for supplying a first gas around the first group dielectric substance; and
first group antennas for generation of first plasma disposed around the first group dielectric substance,
wherein the first group antennas are electrically connected in parallel,
wherein each of the second plasma sources comprises:
a second group dielectric substance mounted in a second group through-hole formed at the chamber;
second gas supply means for supplying a second gas around the second group dielectric substance; and
second group antennas for generation of second plasma disposed around the second group dielectric substance, and
wherein the second group antennas are electrically connected in parallel.

16. The substrate processing apparatus of claim 13, wherein the first power distribution unit comprises:
a first conductive outer cover covering the first power distribution line and being grounded; and
first ground lines of the same length each having one end connected to the first conductive outer cover and the other end connected to a first group antenna,
wherein distances between an input terminal of the first power distribution unit and the first group antennas are equal to each other,
wherein the second power distribution unit comprises:
a second power distribution line;
a second conductive outer cover covering the second power distribution line and being grounded; and
second ground lines of the same length each having one end connected to the second conductive outer cover and the other end connected to the second group antenna, and
wherein distances between an input terminal of the second power distribution unit and the second group antennas are equal to each other.

17. The substrate processing apparatus of claim 13, wherein the first plasma sources are disposed at regular intervals along a circle having a constant radius in the center of the cylindrical chamber, and
wherein the second plasma sources are disposed between the first plasma sources at regular intervals along a circle having a constant radius in the center of the cylindrical chamber.

18. The substrate processing apparatus of claim 13, wherein the first power distribution unit comprises:
an input branch in the form of a coaxial cable to receive power from the first RF power source; and
a three-way branch connected to the input branch and in the form of a coaxial cable branching out three ways, and
wherein the second power distribution unit comprises:
an input branch in the form of a coaxial cable to receive power from the second RF power source; and
a three-way branch connected to the input branch and in the form of a coaxial cable branching out three ways.

19. The substrate processing apparatus of claim 13, wherein the first RF power source and the second RF power source are synchronized with each other to operate in a pulse mode and provide outputs at different times.

20. The substrate processing apparatus of claim 13, further comprising:
a single third plasma source disposed in the center of the chamber to receive a third gas; and
a third RF power source supplying power to the third plasma source,
wherein the third gas includes at least one of the first gas, the second gas, an inert gas, and a nitrogen gas.
